(19) United States
(12) Patent Application Publication
(10) Pub. No.: US 2012/0169189 A1
(43) Pub. Date: Jul. 5, 2012

(54) ELECTRONIC DEVICE ENCLOSURE

(75) Inventors: CHEN-LU FAN, Tu-Cheng (TW); JING-CHAO LIANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/278,446

(22) Filed: Oct. 21, 2011

(30) Foreign Application Priority Data
Dec. 31, 2010 (CN) 201010619598.4

(51) Int. Cl. H05K 5/02

(52) U.S. Cl. 312/223.1

(57) ABSTRACT

An electronic device enclosure for receiving hard disk drives is disclosed. The electronic device enclosure comprises at least one chassis comprising a bottom plate, a side plate, and a middle plate attached to the side plate; the middle plate is substantially parallel to the bottom plate; and a separating assembly located between the bottom plate and the middle plate, the separating assembly comprising a flange, the flange comprising at least one first resisting portion and at least one second resisting portion; the at least one first resisting portion is on a first plane that is substantially parallel to the bottom plate, and the at least one second resisting portion is on a second plane; wherein the at least one first resisting portion and the at least one second resisting portion are adapted to hold hard disk drives received in the at least one chassis.

### BACKGROUND

1. Technical Field

The present disclosure relates to electronic device enclosures, more particularly to an enclosure for receiving hard disk drives.

2. Description of Related Art

An electronic device enclosure may have a housing to receive hard disk drives and include a bottom wall, two sidewalls and a top wall. A plurality of separating plates and a plurality of mounting plates may be located between the top wall and the bottom wall, to divide the housing to a plurality of receiving space. Each mounting plate may be attached to each separating plate. Usually, screws are used to secure the mounting plate to the separating plate, which processes are time-consuming and inconvenient to secure the mounting plate using additional screws.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partially exploded, cutaway view of an electronic device enclosure in accordance with an embodiment.

FIG. 2 is an isometric view of a separating plate in accordance with an embodiment.

FIG. 3 is a semi-assembled electronic device enclosure of FIG. 1.

FIG. 4 is an assembled view of FIG. 1.

FIG. 5 is a side view of a middle hard disk drive and the separating plate.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

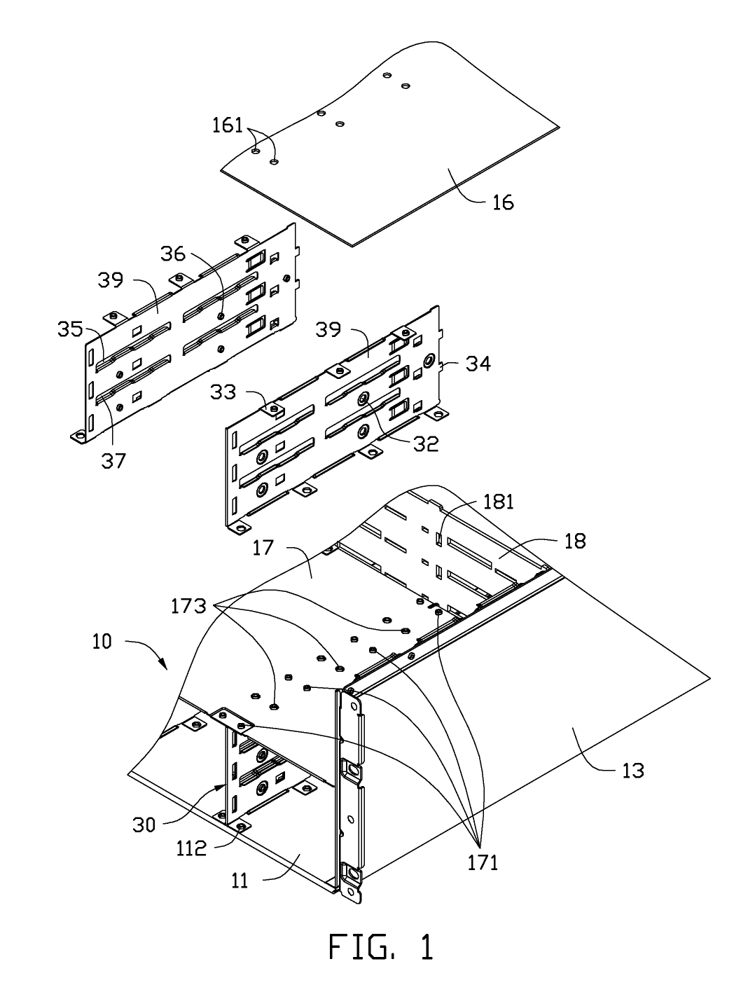

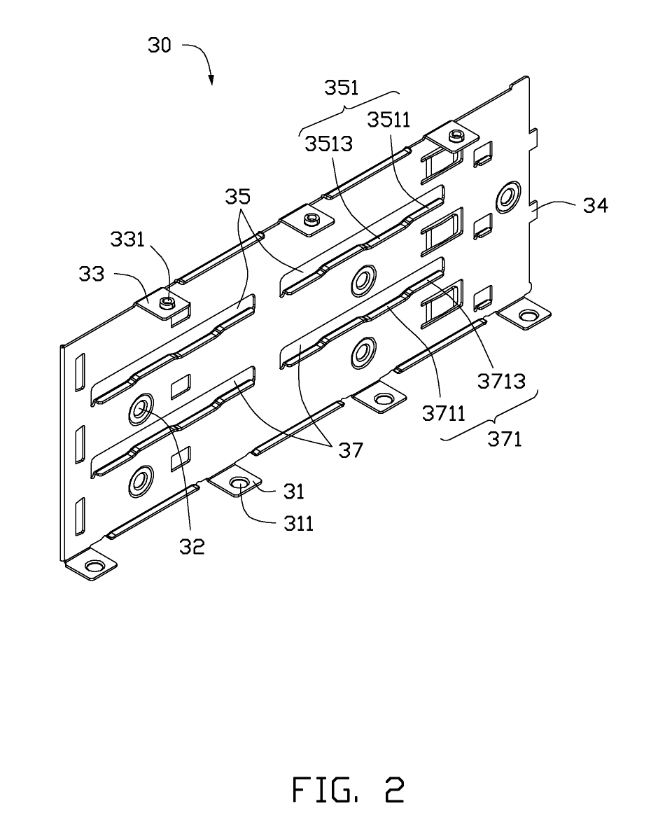

Referring to FIGS. 1 and 2, an electronic device enclosure in accordance with an embodiment includes a bracket 10 and a plurality of separating assembly 30 received in the bracket 10. In one embodiment, the bracket 10 receives a plurality of hard disk drives.

The bracket 10 includes a bottom plate 11, two side plates 13 (only one is shown in FIG. 1) connected to opposite sides of the bottom plate 11, a top plate 16 covering the bracket 10, and a middle plate 17 connected to the two side plates 13. In one embodiment, the top plate 16 is substantially parallel to the middle plate 17 and the bottom plate 11, and the side plates 13 are substantially perpendicular to the bottom plate 11.

A plurality of securing portions 112 (two shown in FIG. 1) protrudes from the bottom plate 11. In one embodiment, each of the plurality of securing portion 112 may be a securing post, or a securing pin. The plurality of securing portions 112 are grouped in 4 by 2 grids in a X and a Y axes, respectively; wherein the X axis is substantially parallel to the side plate 13, and the Y axis is substantially perpendicular to the side plate 13. A plurality of receiving holes 161 are defined in the top plate 16. In one embodiment, six of the plurality of receiving holes 161 are arranged in a pattern which is repeated through out the top plate 16.

The middle plate 17 includes a plurality of first positioning portion 171 and a plurality of second positioning portion 173. In one embodiment, each of the plurality of first positioning portion 171 has a same configuration as each of the plurality of securing portion 112. Each of the plurality of second positioning portion 173 may be a positioning hole, or a positioning slot. The plurality of first positioning portion 171 and the plurality of second positioning portion 173 are grouped in 7 by 2 grids in the X and Y the axes, respectively. Every four of the plurality of first positioning portion 171 and every three of the plurality of second positioning portion 173 are arranged in the X axis.

A retaining plate 18, mounted on a backside of the bottom plate 11, defines a plurality of mounting slots 181. In one embodiment, every four of the plurality of mounting slots 181 are arranged in Z axis substantially perpendicular to the bottom plate 11.

In one embodiment, the separating assembly 30 includes two separating plates 39 arranged back to back, as shown in FIG. 1. An embodiment of the separating assembly 30 comprising one separating plate 39 is shown in FIG. 2. The separating plate 39 has four first securing pieces 31, each with a securing hole 311, extending from a first side of the separating plate 39. Three second securing pieces 33, each with a securing post 331, extend from a second side, opposite to the first side of the separating plate 39. Two mounting tabs 34, corresponding to the mounting slots 181 of the retaining plate 18, extend from a third side of the separating plate 39. In one embodiment, the separating plate 39 is made of a metallic material.

Each separating plate 39 defines two first openings 35 arranged in a first line, and two second openings 37 arranged in a second line. The second line is substantially parallel to the first line. A first flange 351 extends from an edge of each first opening 35, and a second flange 371 extends from an edge of each second opening 37. In one embodiment, the second flange 371 has a same configuration as the first flange 351, wherein the first and second flanges 351, 371 are curved, such as wave-shaped.

In one embodiment, the first flange 351 includes two first resisting portions 3511 and two first abutting portions 3513. The first abutting portions 3513 and the first resisting portions 1511 are alternatively connected to each other. The two first resisting portions 3511 are located on a first plane substantially parallel to the bottom plate 11. The two first abutting portions 3513 are located on a second plane different from the first plane. In one embodiment, the second plane is under the first plane in relation to the bottom plate 11, and is also substantially parallel to the bottom plate 11.

In one embodiment, the second flange 371 includes two second resisting portions 3713 and two second abutting portions 3711. The second resisting portions 3713 and the second abutting portions are alternatively connected to each other. The two second resisting portions 3713 are located on a third plane substantially parallel to the bottom plate 11. The two second abutting portions 3711 are located on a fourth plane different from the third plane. In one embodiment, the third plane is underneath the first plane in relation to the bottom plate 11, and is also substantially parallel to the bottom plate 11.

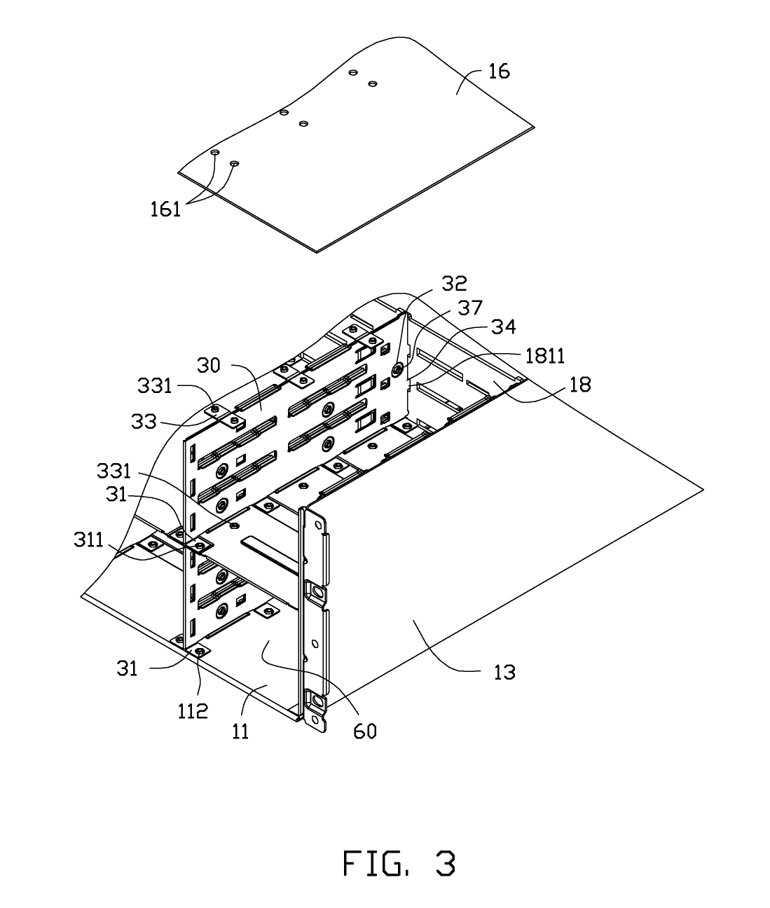

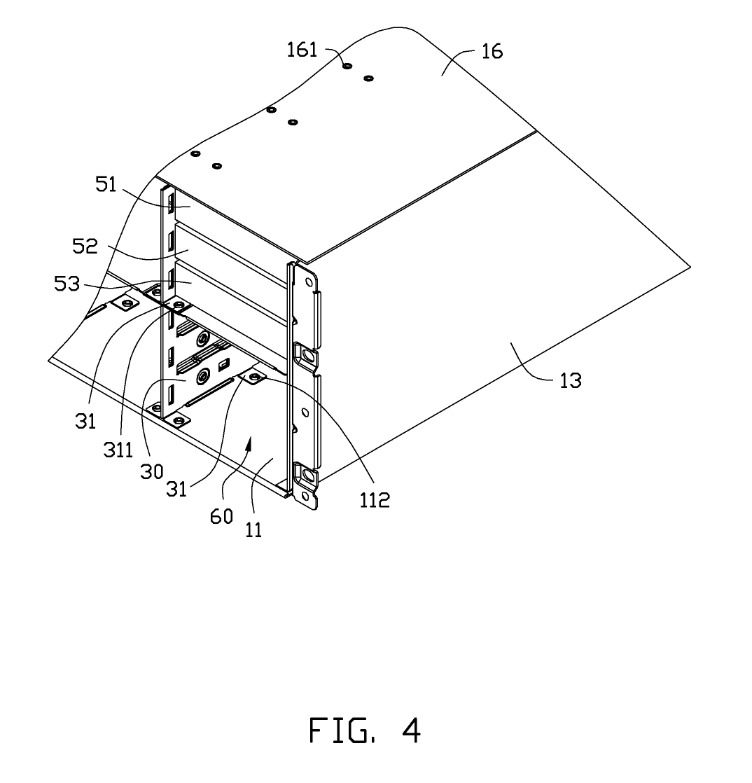

Referring to FIGS. 3-4, in assembly, the retaining plate 18 is detached from the bottom plate 11. A plurality of the separating assemblies 30, each having two separating plates 39 abut back to back against each other, is located between the bottom plate 11 and the middle plate 17. The securing portions 112 are received in the corresponding securing holes 311, and the securing posts 331 are received in the corresponding second positioning portions 173. Another plurality of the separating assemblies 30, each having two separating plates 39 abut back to back against each other, is located between the middle plate 17 and the top plate 16. The first positioning portions 171 are received in the corresponding the securing holes 311, and the securing posts 331 is received in the corresponding receiving holes 161. In one embodiment, two separating plates 39 maybe secured together by means for attaching, such as screws, jointing. For example, in FIG. 1 four mounting holes 32 are defined in one separating plate 39, and four mounting posts 36 protrude from the other separating plate 39. Therefore, the four mounting posts 36 may be engaged in the four mounting holes 32 to secure the two separating plates 39 together.

After placing the separating assemblies 30 and the middle plates 17, the retaining plate 18 is placed on the bottom plate 11 between the two side plates 13. The mounting tabs 34 are received in the mounting slot 181, to secure the retaining plate 18 to the separating plates 39. The middle plate 17 and the plurality of separating assemblies 30 together divide the bracket 10 into a plurality of chassis 60 to house a plurality of hard disk drives 51, 52, 53 as shown in FIG. 4.

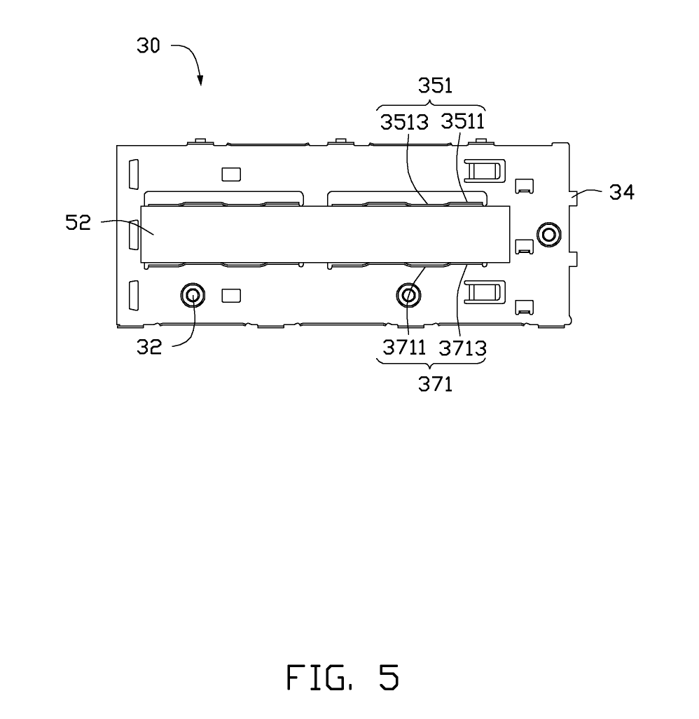

Referring to FIGS. 4-5, in use, a top hard disk drives 51, a middle hard disk drive 52, and a bottom hard disk drive 53 are received in one of the plurality of chassis 60. The first resisting portions 3511 abut to the bottom surface of the top hard disk drive 51, to support the top hard disk drive 51. The first abutting portions 3513 abut on a top surface of the middle hard disk drive 52, and the second resisting portions 3713 abut the bottom surface of the middle hard disk drive 52. Thus, the middle hard disk drive 52 is sandwiched between the first abutting portions 3513 and the second resisting portions 3713. The second abutting portions 3711 abut on the top surface of the bottom hard disk drive 53, to position the bottom hard disk drive 53 to the middle plate 17.

Referring to FIG. 5, when the middle hard disk drive 52 is sandwiched between the first abutting portions 3513 and the second resisting portions 3713, a first gap is defined between the first resisting portion 3511 and the middle hard disk drive 52, and a second gap is defined between the second abutting portion 3711 and the middle hard disk drive 52. Therefore, when the top hard disk drives 51, the middle hard disk drive 52, and the bottom hard disk drive 53 would be vertically spaced in relation to the bottom plate 11 with the first gap or the second gap. The first gap or the second gap is the vertical distance between the first resisting portion 3511 and the first abutting portions 3513. The first gap or the second gap is also the vertical distance between the second abutting portion 3711 and the second resisting portions 3713.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
at least one chassis comprising a bottom plate, a side plate, and a middle plate attached to the side plate; the middle plate is substantially parallel to the bottom plate; and
a separating assembly located between the bottom plate and the middle plate, the separating assembly comprising a flange, the flange comprising at least one first resisting portion and at least one second resisting portion; the at least one first resisting portion is on a first plane that is substantially parallel to the bottom plate, and the at least one second resisting portion is on a second plane;
wherein the at least one first resisting portion and the at least one second resisting portion are adapted to hold hard disk drives received in the at least one chassis.

2. The electronic device enclosure of claim 1, wherein the at least one first resisting portion and the at least one second resisting portion are alternatively connected to each other.

3. The electronic device enclosure of claim 1, wherein the second plane is substantially parallel to the first plane.

4. The electronic device enclosure of claim 1, wherein the flange is curved.

5. The electronic device enclosure of claim 1, wherein the flange is wave-shaped.

6. The electronic device enclosure of claim 1, wherein a securing portion is located on the bottom plate; and a first positioning portion is located on the middle plate; the first positioning portion and the securing portion have a same configuration and the first positioning portion is aligned with the securing portion, and the separating assembly comprising a first securing piece capable of engaging with the securing portion or the first positioning portion.

7. The electronic device enclosure of claim 6, wherein the first positioning portion and the securing portion are aligned substantially perpendicular to the bottom plate.

8. The electronic device enclosure of claim 6, wherein the securing portion is a post, and a securing hole is defined in the first securing piece to receive the securing portion.

9. The electronic device enclosure of claim 1, further comprising a retaining plate, the separating assembly comprises a mounting tab, wherein the mounting tab is capable of engaging with the retaining plate.

10. The electronic device enclosure of claim 1, wherein the separating assembly comprises two separating plates attached together with the flanges of each of the two separating plates facing away from each other.

11. An electronic device enclosure comprising:
at least one chassis comprising a bottom plate, two side plates connected to the bottom plate, and a middle plate attached to the two side plates; the middle plate is substantially parallel to the bottom plate;
a separating assembly located between the bottom plate and the middle plate, wherein the separating assembly comprises at least one opening; and
a flange extending from an edge of the at least one opening, wherein the flange is curved; the flange comprises at least one first resisting portion and at least one second resisting portion which are alternatively connected to each other, the at least one first resisting portion is a first end of the flange, and the at least one second resisting portion is a second end of the flange,
wherein the at least one first resisting portion and the at least one second resisting portion are adapted to hold hard disk drives received in the at least one chassis.

12. The electronic device enclosure of claim 11, wherein the at least one first resisting portion is on a first plane substantially parallel to the bottom plate, and the at least one second resisting portion is on a second plane.

13. The electronic device enclosure of claim 12, wherein the second plane is substantially parallel to the first plane.

14. The electronic device enclosure of claim 11, wherein the flange is wave-shaped.

15. The electronic device enclosure of claim 11, wherein a securing portion is located on the bottom plate; a first positioning portion is located on the middle plate, the first positioning portion and the securing portion have a same configuration, and the separating assembly comprising a first securing piece capable of engaging with the securing portion or the first positioning portion.

16. The electronic device enclosure of claim 15, wherein the first positioning portion and the securing portion are aligned substantially perpendicular to the bottom plate.

17. The electronic device enclosure of claim 15, wherein the securing portion is a post, and a securing hole is defined in the first securing piece to receive the securing portion.

18. The electronic device enclosure of claim 11, further comprising a retaining plate, the separating assembly comprising a mounting tab, wherein the mounting tab is capable of engaging with the retaining plate.

19. The electronic device enclosure of claim 11, wherein the separating assembly comprises two separating plates attached together with the flanges of each of the two separating plates facing away from each other.

20. The electronic device enclosure of claim 11, wherein the at least one chassis further comprises a top plate covered on the two side plates, the top plate is substantially parallel to the middle plate, and the separating assembly is located between the top plate and the middle plate.
